(19) United States
(12) Patent Application Publication
(10) Pub. No.: US 2025/0192207 A1
(43) Pub. Date: Jun. 12, 2025

(54) FUEL CELL POWER SYSTEM

(71) Applicant: Caterpillar Inc., Peoria, IL (US)

(72) Inventors: Umakanth Sakaray, Dunlap, IL (US); Pavan Kumar Reddy Kudumula, Dunlap, IL (US); Venkatakrishnan Bala, Morton, IL (US); Parag Mehresh, Peoria, IL (US); Darragh Reilly, Peoria Heights, IL (US)

(73) Assignee: Caterpillar Inc., Peoria, IL (US)

(21) Appl. No.: 18/530,525

(22) Filed: Dec. 6, 2023

(51) Int. Cl. H01M 8/04701; H01M 8/04007; H01M 8/04014; H01M 8/04029; H01M 8/04746; H01M 8/04828; H01M 8/0662; H01M 8/10; H05K 7/20

(52) U.S. Cl. CPC H01M 8/04731; H01M 8/04014; H01M 8/04029; H01M 8/04067; H01M 8/04701; H01M 8/04768; H01M 8/04828; H01M 8/0687; H05K 7/20909; H01M 2008/1095

(57) ABSTRACT

A fuel cell power system is disclosed comprising: a container; a fuel cell stack; power electronics and a battery electrically connected to the fuel cell stack. A plurality of heat exchangers are mounted on a plurality of walls on the container, each heat exchanger having an inlet louver for drawing outside air into the container. A plurality of coolant lines are connected to the plurality of heat exchangers. At least one of the coolant lines circulates hot coolant from the fuel cell power system to the heat exchanger. At least one of the coolant lines circulates cold coolant to the fuel cell stack. A pump transfers coolant throughout the coolant lines. A plurality of fan assemblies are mounted on top of the container, the plurality of fan assemblies are configured to draw the outside air through the heat exchangers and expel exhaust air out of the container.

### TECHNICAL FIELD

The present disclosure generally relates to hydrogen power units, and more particularly relates to thermal management systems for hydrogen fuel cell power containers.

### BACKGROUND

Hydrogen (“H2”) power units such as fuel cells, hydrogen fueled internal combustion engines, and their associated fuel storage systems play a significant role in the pursuit of clean and efficient energy solutions. Fuel cells have gained considerable traction as an alternative source of power, and they are often used in applications ranging from transportation to stationary power generation.

A hydrogen fuel cell is an electrochemical device that converts the chemical energy stored in hydrogen fuel into electricity, with water as a byproduct. Fuel cells operate through a redox reaction between hydrogen and oxygen, typically using a proton exchange membrane (PEM) or an alkaline electrolyte, which typically uses hydrogen as the fuel and oxygen from the air as the oxidant. In these cells, hydrogen gas is fed into the anode where it is oxidized to produce protons and electrons. The protons move through the membrane to the cathode, while the electrons flow through an external circuit to produce electricity. At the cathode, oxygen molecules react with the incoming protons and electrons to form water. A hydrogen internal combustion engine, on the other hand, operates similarly to a traditional internal combustion engine but uses hydrogen as the fuel instead of gasoline or diesel.

Fuel cell power systems are generally complex and include various auxiliary systems for cooling, air intake, and power regulation. These systems require robust cooling systems to manage the heat produced during the electrochemical reactions in the fuel cell stack. Heat removal is crucial, as the stack coolant accounts for over 50% of the total chemical energy. The operating temperature range for the stack coolant is typically 60-65° C. for optimal fuel cell performance. Furthermore, the use of power conversion electronics and auxiliary devices like electric motors to drive fans and pumps add complexity to the system, requiring extra space and increasing overall costs. Despite the absence of traditional combustion processes, fuel cell stacks still produce a considerable amount of heat due to the exothermic nature of the chemical reactions involved. This heat throughout must be effectively managed to maintain optimal operating conditions for the fuel cell stack.

Others have attempted to develop systems for cooling fuel cell stacks but have not fully addressed issues like space constraints, cooling efficiency, and ambient temperature control in a container. For instance, CN215266399U (hereinafter referred to as “the CN reference”) discloses a fuel cell power system that falls within the technical field of fuel cells. However, while the CN reference lacks a comprehensive approach to managing space limitations, optimizing cooling efficiency, and maintaining ambient temperature within the container. Thus, there remains a need for improvement in these areas.

It can therefore be seen that a need exists for compact power energy systems with efficient thermal energy system management.

### SUMMARY

In accordance with one aspect of the disclosure, a fuel cell power system is disclosed. The fuel cell power system comprises: a container having a single compartment; a fuel cell stack; a set of power electronics and a battery electrically connected to the fuel cell stack; a plurality of heat exchangers mounted on a plurality of walls on the container, each heat exchanger having an inlet louver for drawing outside air into the container; a common manifold connecting a plurality of coolant lines to the plurality of heat exchangers, at least one of the plurality of coolant lines circulating hot coolant from the fuel cell power system to the plurality of heat exchangers, and at least one of the plurality of coolant lines circulating cold coolant to the fuel cell power system; a pump for transferring coolant throughout the plurality of coolant lines; and a plurality of fan assemblies mounted on top of the container, the plurality of fan assemblies are configured to draw the outside air through the plurality of heat exchangers and expel exhaust air out of the container.

In accordance with another aspect of the disclosure, a thermal management system for a containerized fuel cell power system is disclosed. The thermal management system comprises: a plurality of heat exchangers integrated in a plurality of walls of a container, each heat exchanger configured to draw an outside air into the container, the container having a fuel cell, power electronics, and a battery; a common manifold connecting a plurality of coolant lines to the plurality of heat exchangers; a pump configured to transfer coolant throughout the plurality of coolant lines, at least one of the plurality of coolant lines configured to circulate the coolant from the fuel cell to the plurality of heat exchangers, and at least one of the plurality of coolant lines configured to circulate the coolant to the containerized fuel cell power system; a plurality of fan assemblies mounted on the container, the plurality of fan assemblies configured to draw the outside air through the plurality of heat exchangers into the container and further configured to expel exhaust air from the container; a thermostat and a plurality of thermocouples in communication with the thermostat, the plurality of thermocouples are provided throughout the containerized fuel cell power system; and a control unit in communication with the thermostat, the pump, and the plurality of fan assemblies, the control unit configured to modulate the pump and operations of the plurality of fan assemblies based on temperature readings received from the thermostat.

In accordance with another aspect of the disclosure, a method for producing electric power in a containerized fuel cell power system is disclosed. The method comprises: providing a fuel cell stack, power electronics, a battery, and a control unit within a container; integrating a plurality of heat exchangers into walls of the container; mounting a plurality of fan assemblies on the container for thermal management; activating the containerized fuel cell power system for electric power generation; activating the containerized fuel cell power system for electric power generation; and initiating power generation in the fuel cell stack by transforming hydrogen and oxygen into electricity and water.

These and other aspects and features of the present disclosure will be better understood upon reading the following detailed description when read in conjunction with the accompanying drawings.

### BRIEF DESCRIPTION OF THE DRAWINGS

FIG. 1 is a perspective view of a fuel cell power system, according to an embodiment of the present disclosure.

FIG. 2 is a perspective view of the fuel cell power system of FIG. 1 in an open configuration, according to an embodiment of the present disclosure.

FIG. 3 is a perspective flow chart of a door assembly of the fuel cell cooling system of FIG. 2, according to an embodiment of the present disclosure.

FIG. 4 is a schematic of the fuel cell power system of FIG. 1, according to an embodiment of the present disclosure.

FIG. 5 is a perspective view of the fuel cell power system of FIG. 1 without frames, according to an embodiment of the present disclosure.

FIG. 6 is a close-up perspective view of a door on the fuel cell power system of FIG. 2, according to an embodiment of the present disclosure.

FIG. 7 is a perspective view of the fuel cell power system of FIG. 2 without frames, according to another embodiment of the present disclosure.

FIG. 8 is a close up of a fan system on the fuel cell power system of FIG. 2, according to an embodiment of the present disclosure.

FIG. 9 is a schematic of a cooling system for the fuel cell power system of FIG. 1, according to an embodiment of the present disclosure.

FIG. 10 is a block diagram of a thermal management system for the fuel cell power system of FIG. 1, according to an embodiment of the present disclosure.

FIG. 11 is a flow-chart of a method of conserving hydrogen in the H2 fuel system of the work machine of FIG. 1, according to an embodiment of the present disclosure.

The figures depict one embodiment of the presented disclosure for purposes of illustration only. One skilled in the art will readily recognize from the following discussion that alternative embodiments of the structures and methods illustrated herein may be employed without departing from the principles described herein.

### DETAILED DESCRIPTION

Referring now to the drawings, and with specific reference to the depicted example, a fuel cell power system 100 is shown, illustrated as a containerized fuel cell power system. While the following detailed description describes an exemplary aspect in connection with the containerized energy systems powered by fuel cells, it should be appreciated that the description applies equally to the use of the present disclosure in other energy storage containers powered by, including, but not limited to, generators, hydrogen energy systems, renewable energy, backup power systems, industrial applications, and mobile power solutions that require thermal management systems, as well.

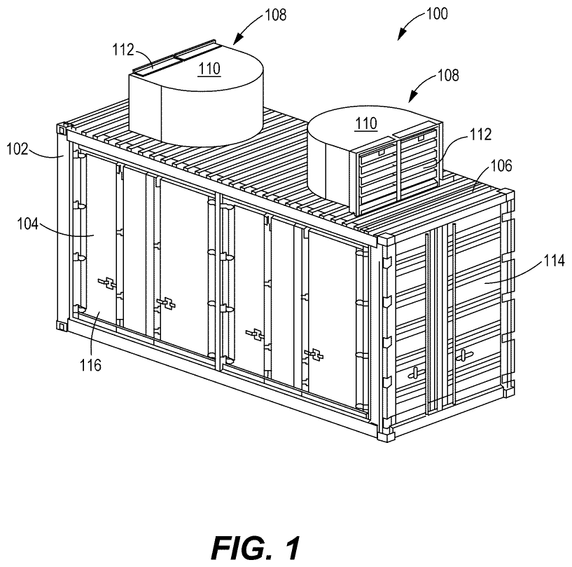

Referring to FIG. 1, the fuel cell power system 100 is illustrated, according to one embodiment of the disclosure. The fuel cell power system 100 comprises of a container 102 having walls 104, a roof 106, and a floor (not shown). The container 102 may be engineered as a single compartment to house various elements, as well as being designed to fit within the constraints of shipping containers, such as ISO-containers, and referred as a containerized fuel cell power system, as generally known in the arts. The container 102 is made of high-strength metal alloys, or alternative materials such as reinforced composites. The walls 104 are made from reinforced steel or high-strength composites to serve as the structural framework of the container 102. The walls 104 may include insulation or other thermal management materials to maintain internal temperatures.

The fuel cell power system 100 further includes a plurality of fan assemblies 108 each having a duct assembly 110 for directing airflow. The duct assembly 110 includes a fan louver 112 for controlled passage of air. The fuel cell power system 100 further includes a container end 114 and a plurality of doors 116 for easy access to the internal components of the fuel cell power system 100. The container end 114 and the doors 116 facilitate access for maintenance or component replacement. The doors 116 may be sealed with gaskets to maintain an environmentally controlled internal atmosphere.

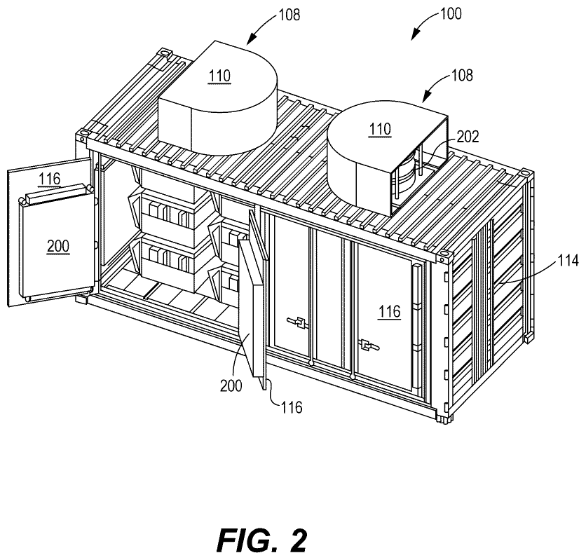

Referring to FIG. 2, the fuel cell power system 100 is illustrated with a pair of doors 116 open, according to one embodiment of the disclosure. As depicted in FIG. 2, a plurality of heat exchangers 200 are integrated with the walls 104 and/or doors 116 of the container 102. The plurality of heat exchangers 200 may include various types such as radiators, plate heat exchangers, shell and tube heat exchangers, or finned-tube heat exchangers, each designed to facilitate efficient heat transfer. The plurality of heat exchangers 200 may be constructed from materials such as aluminum, copper, stainless steel, or other thermally conductive materials to ensure efficient heat dissipation. The plurality of fan assemblies 108 may include a centrifugal fan 202

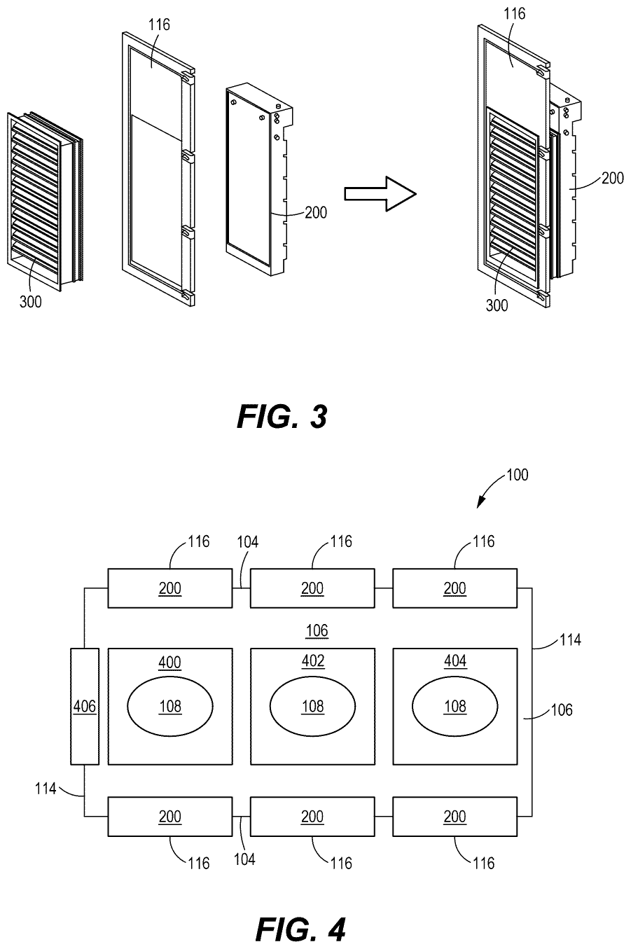

Referring to FIG. 3, an illustration of the assembly of one of the doors 116 integrated with one of the plurality of heat exchangers 200, according to an embodiment of the disclosure. Each of the plurality of heat exchangers 200 may comprise an air inlet louver 300 designed to filter all outside air that is drawn into the container 102. The air inlet louver 300 is strategically positioned to draw in outside air, which subsequently flows through the plurality of heat exchangers 200 for cooling purposes. The air inlet louver 300 may be constructed from a variety of materials such as aluminum, stainless steel, or coated steel, and is designed with angled slats to mitigate the ingress of water and debris into the system. Optionally, the air inlet louver 300 may include a mesh or screen for additional filtration designed to prevent the ingress of water and debris. The air inlet louver 300 may be adjustable to modulate airflow and may be coated with water-repellent materials for enhanced protection

The plurality of heat exchangers 200 within the doors 116 can be of different types, such as plate-fin, shell-and-tube, or microchannel, depending on specific thermal management requirements. This design allows for a more streamlined cooling process, utilizing both the walls 104 and doors 116 of the container 102 as multifunctional components that contribute to maintaining an optimal temperature range within the container. By integrating the plurality of heat exchangers 200 into the doors 116, the system offers a compact and efficient way to manage heat while maximizing space utilization within the container 102.

Referring to FIG. 4, a top-view schematic diagram of the fuel cell power system 100 is illustrated, according to one embodiment of the disclosure. The container 102 is engineered with a single compartment to house a fuel cell stack 400, power electronics 402, and a battery 404 for the fuel cell power system 100. The fuel cell power system 100 may also include a control unit 406 mounted on one of the doors 116 or inside the container 102. The control unit 406 may be designed to manage the flow of hydrogen gas to the fuel cell stacks, control the power output, monitor overall system health, and ensure safety measures are in place. The control unit 406 facilitates system monitoring and operation, and may further be digitally interfaced with a microcontroller which in turn is connected to the battery 404. The battery 404 may serve as a backup power source and can be of various types, including but not limited to, lithium-ion, nickel-metal hydride, or lead-acid batteries.

The control unit 406 may feature a touch screen interface and a variety of input/output ports for real-time monitoring and system adjustments, as well as including communication capabilities such as WIFI, 5G, LTE, or other mobile cellular service to communicate with a back-office system or offsite team, as generally known in the arts. The control unit 406 is configured to interact seamlessly with the fuel cell stack 400, the power electronics 402, and the battery 404 to optimize system performance while maintaining safety protocols, thereby enabling efficient and secure operation of the fuel cell power system 100.

As shown in FIG. 4, a plurality of fan assemblies 108 are positioned top of the roof 106 to draw hot air out of the container 102 to cool the interior compartment of the container 102 for further cooling the fuel cell stack 400, the power electronics 402, and the battery 404 to prevent overheating and for promoting efficient operation. The fan assemblies 108 are configured to draw air through the plurality of heat exchangers 200 and subsequently expel exhaust out of the container 102. Integrated with the walls 104 and/or doors 116 of the container 102 are the plurality of heat exchangers 200, such as shown in FIG. 3.

Fans in the fan assemblies 108 may be of the centrifugal, axial flow, or bladeless types as an alternative. Expanding on the types of fans that can be used in the fan assemblies 108, a variety of fan configurations may be employed to achieve optimal cooling performance. Centrifugal fans, for example, utilize a rotating impeller to move air radially, often providing higher pressure capabilities compared to other fan types. Axial flow fans, another option, move air along the axis of the fan, providing high flow rates but generally lower pressure. These are useful for quick evacuation of hot air from the container 102. Bladeless fans use a brushless electric motor to draw in air and push it out through a circular or annular aperture, providing a less turbulent airflow and quieter operation. Each type of fan offers specific advantages, such as energy efficiency, noise reduction, or ease of maintenance, and the selection may depend on the specific cooling requirements of the fuel cell power system 100.

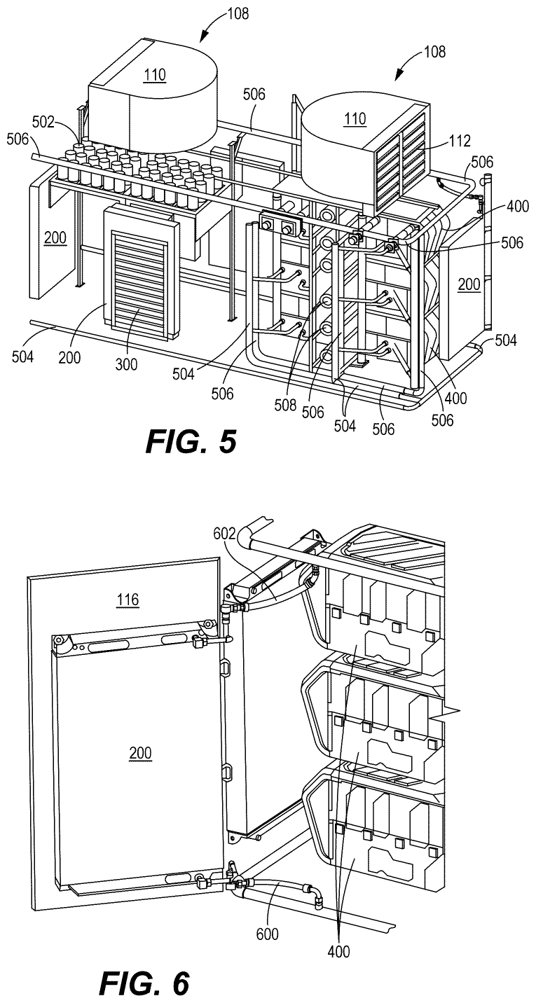

Referring to FIG. 5, a perspective view of the fuel cell power system 100 without the container 102 is illustrated, according to one embodiment of the disclosure. In one embodiment, the fuel cell power system 100 comprises the fuel cell stack 400, DC choke stack 502, a common manifold 500 that connects to both a plurality of cold coolant lines 504 and a plurality of hot coolant lines 506 (collectively “coolant lines 504, 506”). The common manifold 500 serves as a hub, standardizing the coolant flow. There may also be an air filter 508 for filtering air used for hydrogen combustion in the fuel cell stack 400.

At least one of the hot coolant lines 506 transfers hot coolant from the fuel cell stack 400 to the heat exchangers 200. At least one of the cold coolant lines 504 pumps cold coolant back to the fuel cell stack 400. The coolant lines 504, 506 may be fabricated from reinforced rubber or metal tubing, capable of handling the elevated temperatures and pressures within the system. There may be a coolant reservoir (not shown) in fluid communication with the coolant lines 504, 506, as well as a set of valves integrated within the coolant lines 504, 506, permitting selective control of coolant flow through individual lines, enabling efficient temperature regulation.

The system also includes the DC choke stack 502 positioned near the top of the container 102, allowing DC choke exhaust to be expelled through the plurality of fan assemblies 108. The DC chokes may be implemented as laminated iron-core inductors or toroidal inductors and are connected via high-conductivity electrical cables to the power electronics 402 and fuel cell stack 400.

Referring to FIG. 6, a close-up perspective view of one of the heat exchangers 200 in the fuel cell power system 100 is illustrated, according to one embodiment of the disclosure. Each of the plurality of heat exchangers 200 includes a radiator outlet lines 600 and a radiator inlet line 602 for transferring coolant via the plurality of cold coolant lines 504 and hot coolant lines 506.

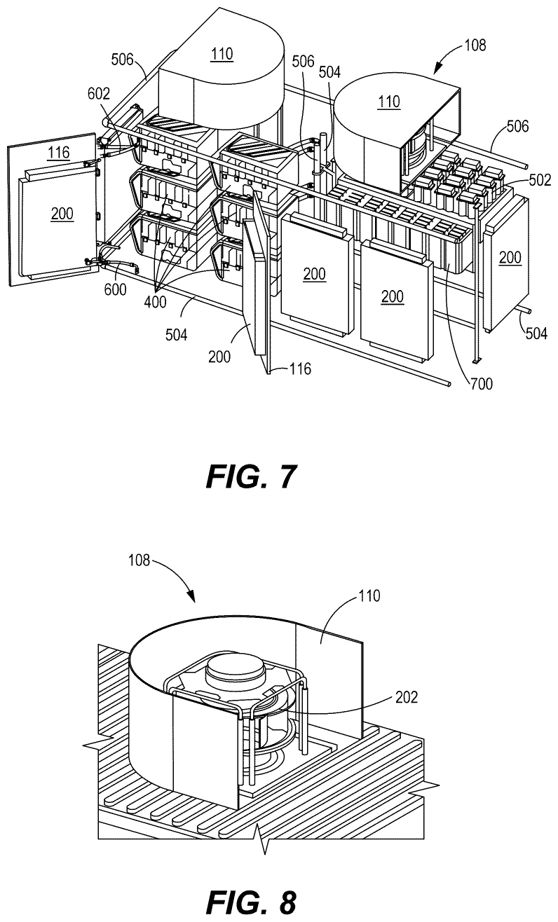

Referring to FIG. 7, a perspective view of the fuel cell power system 100 without the container 102 is illustrated, according to another embodiment of the disclosure. In one embodiment, the fuel cell power system 100 comprises a power distribution unit 700 connected to the fuel cell stack 400 and the DC choke stack 502. The fuel cell power system 100 also includes the common manifold 500 that connects to both a plurality of cold coolant lines 504 and a plurality of hot coolant lines 506. The common manifold 500 also serves as a hub, standardizing the coolant flow. The air filter 508 may also be provided for filtering air used for hydrogen combustion in the fuel cell stack 400.

Overall, the fuel cell power system 100 operates as an integrated unit. The fuel cell stack 204 generates electricity and heat. The heat is managed by transferring hot coolant through the hot coolant lines 506 to the heat exchangers 200. Cold coolant from the heat exchangers 200 is then returned to the fuel cell stack 400 via the cold coolant lines 504. The fan assemblies 108 draw air through the heat exchangers 200 and expel it from the container 102, keeping the internal atmosphere in the container 102 at a controlled temperature.

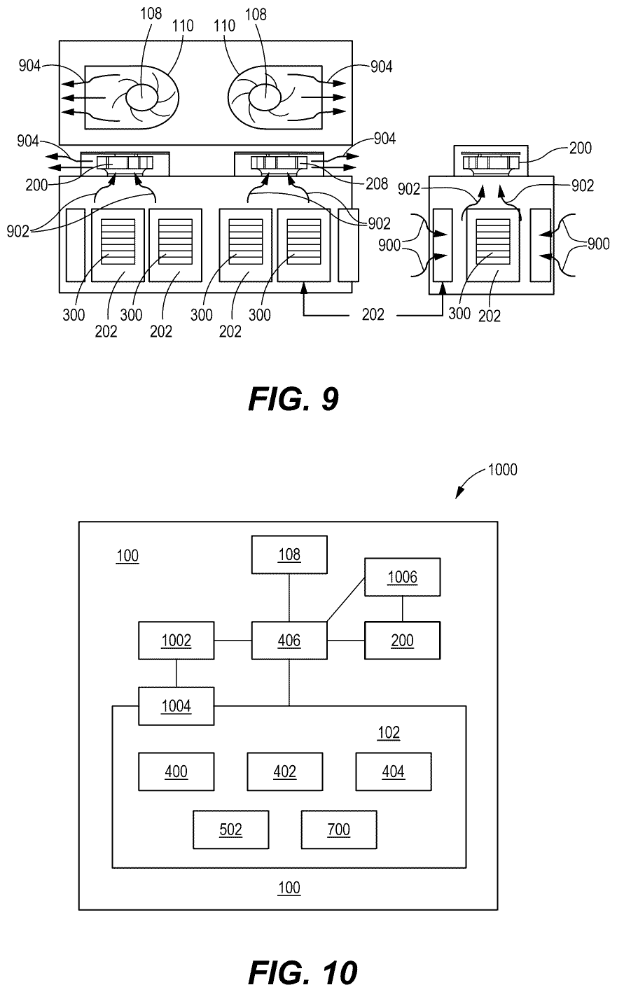

Referring to FIG. 8, a close-up perspective view of one of the fan assemblies 108 in the fuel cell power system 100 is illustrated, according to one embodiment of the disclosure. Each of the fan assemblies 108 may include the duct assembly 110 to draw and direct exhaust air out of the container 102 using the centrifugal fan 202. The fan assemblies 108 are positioned and designed to ensure effective ventilation and cooling within the fuel cell power system 100. The duct assembly 110 channels the flow of air from inside the container 102 to the outside environment. In FIG. 8, the duct assembly 110 is illustrated without a top-cover. The duct assembly 110 may be fabricated from materials such as galvanized steel, aluminum, or high-grade plastic to ensure durability and resistance to corrosion.

Within each fan assemblies 108, the centrifugal fan 202 is employed to move air efficiently. The centrifugal fan 202 operates by using the centrifugal force generated by the high-speed rotation of its blades to accelerate air radially outward. The centrifugal design allows for a high-pressure air flow, providing suitable air movement for cooling the fuel cell stack 400, power electronics 402, the battery 404, the DC choke stack 502, and the power distribution unit 700.

Additionally, the fan assemblies 108 may include the fan louver 112, which can open or close to regulate the exhaust of warm air from the container 102. The fan louver 112 may be manually adjustable or automatically controlled by sensors or the control unit 406 to adapt to varying thermal conditions within the container 102. Alternative types of fans, such as axial fans or bladeless fans, may also be used depending on specific system requirements. These alternative fan types can be easily swapped out or integrated, thanks to the modular design of the fan assemblies 108. Overall, the fan assemblies 108 in conjunction with the duct assembly 110 and the centrifugal fan 202 provide effective thermal management of the fuel cell power system 100.

Referring to FIG. 9, a schematic flow-chart of the air flow in the fuel cell power system 100 is illustrated, according to one embodiment of the disclosure. The air inlet louver 300 is strategically positioned to draw in outside air 900, which subsequently flows through the plurality of heat exchangers 200 for cooling purposes. The plurality of heat exchangers 200 each feature the air inlet louver 300 that is designed to filter the outside air 900, as it enters the container 102. The air inlet louver 300 filters contaminants from the incoming air, and directs the flow of the outside air 900 through the heat exchangers 200, which also helps cool the coolant in the hot coolant lines 506.

Inside the container 102, a container air flow 902 circulates to facilitate internal cooling. The container air flow 902 is drawn from the internal environment of the container 102 and passed through the heat exchangers 200 to absorb the heat generated by the system's components. The plurality of fan assemblies 108, located at the top of the roof 106, are responsible for pulling the container air flow 902 up and out of the container 102, expelling it as exhaust air 904.

The fan assemblies 108 are strategically positioned to maximize air flow, ensuring that the hot air rises and gets efficiently evacuated from the container 102 to help maintain the internal temperature of the container 102, thereby preventing overheating of critical components such as the fuel cell stack 400, power electronics 402, and battery 404. The air flow through the air inlet louver 300, through the plurality of heat exchangers 200, drawn by the plurality of fan assemblies 108, the fuel cell power system 100 achieves a balanced and effective air flow, optimizing both cooling and overall operational efficiency. The fan assemblies 108 are configured to draw the container air flow 902 to expel out of the container 102 as exhaust air 904. The plurality of fan assemblies 108 may include at least two centrifugal fans each having the duct assembly 110 oriented or configured to direct and expel the exhaust air 904 out of the container 102 in opposing airflow directions, for optimal airflow management.

Referring to FIG. 10, a block diagram of a thermal management system 1000 in the fuel cell power system 100 is illustrated, according to one embodiment of the disclosure. The fuel cell power system 100 is equipped with a control unit 406 designed to maintain the temperature of the fuel cell stack 400 within a desired temperature range, e.g. between 60-70 degrees C. The control unit 406 communicates with a thermostat 1002 and a plurality of plurality of thermocouples 1004, which are positioned proximate or near the fuel cell stack 400, the power electronics 402, the battery 404, the DC choke stack 502, the power distribution unit 700, the plurality of heat exchangers 200, the plurality of fan assemblies 108, and provided throughout the container 102. The control unit 406 is also in communication with the pump 1006 which transfers coolant throughout the cold coolant lines 504 and the hot coolant lines 506. The pump 1006 may be a variable-speed pump configured for modulation or variation of speeds by the control unit 406, as generally known in the arts.

The control unit 406 continuously receives temperature data from the plurality of thermocouples 1004 for real-time monitoring of the fuel cell stack 400's temperature. Upon receiving the temperature data, the control unit 406 compares it with the target temperature range set by the thermostat 800. The thermostat 1002 is configured to set a target temperature range between 60-70 degrees Celsius for the fuel cell stack 400. If the temperature falls below or exceeds this range, the control unit 406 activates or deactivates the plurality of heat exchangers 200, the plurality of fan assemblies 108, the pump 1006, and any other component in the fuel cell power system 100 to bring the temperature back within the desired range. The control unit 406 also continuously receives temperature data from the plurality of thermocouples 1004 providing in the cold coolant lines 504 and the hot coolant lines 506 for monitoring temperatures of the coolant.

Furthermore, the control unit 406 can be programmed to send alerts to a back-office system, remotely via wireless communication. The control unit 406 may be configured to initiate a shutdown of the fuel cell stack 400 if the temperature deviates from the set range for an extended period to ensure safety and longevity.

A power management module may be utilized by the control unit 406 in communication with the fuel cell stack 400, the power electronics 402, and the battery 404, regulating power distribution and optimizing energy storage during peak and off-peak periods. A sensor assembly may interface with the power management module, continuously monitoring the energy consumption rates and adjusting the operations of the fuel cell stack 400 and the power electronics 402 accordingly.

The integration of the plurality of heat exchangers 200 as radiators into the structure of the container 102 contributes to effective cooling and also to maintaining a compact form factor for the container 102. The integrated radiators are strategically positioned to maximize cooling efficiency, thereby reducing the need for a larger and more complex cooling system, enabling a more compact and optimized system, increasing the ease of installation, and reducing overall costs. These radiators are made of high-conductivity materials like copper or aluminum, which aids in rapid heat dissipation and helps maintain the fuel cell stack 204 temperature within the desired range.

The compact design facilitated by the integrated radiators also improves space utilization, allowing for more containers to be deployed in a given area, thereby increasing overall power generation capacity. The integrated radiators and control unit 406 may communicate in conjunction to provide a highly efficient, compact, and for optimizing the fuel cell power system 100 for improving overall power generation capacity.

An external interface port may be provided on the container 102, facilitating easy connection to external power grids or other energy-consuming systems, allowing the fuel cell power system 100 to function as a primary or backup power source.

During shutdown procedures, the control unit 406 initiates a cooling protocol to gradually bring the temperature of the fuel cell stack 400 down to a safe level for system shutdown. This ensures that no thermal stress is induced on the fuel cell stack 204, preserving its longevity.

### INDUSTRIAL APPLICABILITY

In operation, the present disclosure may find applicability in numerous sectors, including but not limited to, renewable energy, backup power systems, industrial applications, and mobile power solutions. Specifically, the thermal management and cooling systems and methods of the present disclosure may be used in hydrogen energy systems for various work machines, as well as stationary power systems, emergency backup power systems, and grid-balancing power systems. While the foregoing detailed description is made with specific reference to stationary power systems, it should be understood that its teachings may also be applied to other hydrogen fuel cell applications.

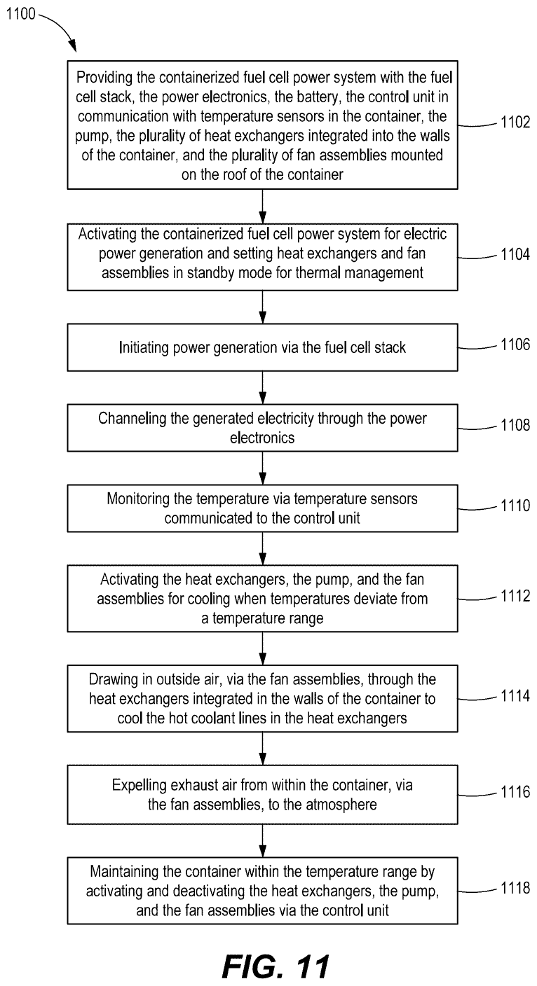

Now referring to FIG. 11, a method 1100 for producing electric power in the fuel cell power system 100 is illustrated, according to one embodiment of the disclosure. In a step 1102, the fuel cell power system 100 is provided with the fuel cell stack 400, the power electronics 402, the battery 404, the control unit 406 in communication with the plurality of thermocouples 1004 in the container 102, the pump 1006, the plurality of heat exchangers 200 integrated into the walls 104 of the container 102, and the plurality of fan assemblies 108 mounted on the roof 106 of the container configured to draw exhaust air 904 out of the container 102.

The power electronics 402 may be positioned adjacent to the fuel cell stack 400 for efficient energy conversion and management. The battery 404 may be placed near the fuel cell stack 400 for energy storage and backup. DC choke stack 502 may be provided with the power electronics 402 and positioned proximate to or near the roof 106 inside the container 102 so that exhaust air 904 from the DC choke stack 502 is quickly removed and drawn out by plurality of fan assemblies 108. The plurality of fan assemblies 108 may be mounted directly above the DC choke stack 502. In the step 1102, the plurality of heat exchangers 200 are aligned at the sides of the container 102 for optimal thermal management by drawing outside air into the container 102 for cooling coolant in the hot coolant lines 506.

In a step 1104, the fuel cell power system 100 is activated for electric power generation by the fuel cell stack 400. Upon system activation, the plurality of heat exchangers 200, the pump 1006, and the fan assemblies 108 are ready to activate when required for thermal management cooling to keep the container 102 within a temperature range or below a temperature threshold.

In a step 1106, the fuel cell stack 400 initiates power generation, via the electrochemical conversion process, transforming hydrogen and oxygen into electricity and water within the fuel cell power system 100.

In a step 1108, the generated electricity is channeled through the power electronics 402 to condition the power to meet the specifications required for the intended loads or external devices. For example, the power distribution unit 700 may distribute the conditioned electrical power to the external loads, which could range from electrical grids to specific devices or systems.

In a step 1114, the control unit 406 initiates continuous monitoring of the temperature of the fuel cell stack 400 via the plurality of thermocouples 1004. The control unit 406 receives a temperature signal from the thermometer sensors 802 and processes the gathered data to determine if cooling action is needed.

In a step 1116, if the temperature in the container 102 deviates from the temperature range or above/below a temperature threshold, such as a target range of 60-70 degrees Celsius, the control unit 406 activates at least one of the plurality of heat exchangers 200, the pump 1006, and fans for cooling the fuel cell stack 400. The pump 1006 is activated to pump the coolant throughout the plurality of cold coolant lines 504 and the plurality of hot coolant lines 506.

In a step 1118, the plurality of heat exchangers 200 start cooling the hot coolant lines 506 by circulating coolant through them, while the plurality of fan assemblies 108 begin drawing in outside air 900. The plurality of fan assemblies 108 draw in outside air 900 through the plurality of heat exchangers 200. The drawn in outside air 900 flows over both the coolant lines 504, 506 inside through plurality of heat exchangers 200 and in the container 102 to cools the hot coolant lines 506 further, ensuring that the entirety of the container 102 stays within the desired thermal range.

In a step 1120, the fan assemblies 108 mounted on the roof 106 of the container 102 begin to draw out the exhaust air 904, which has been warmed by the fuel cell stack 400, the power electronics 402, and the battery 404, effectively removing excess heat from the container 102. This exhaust air 904 is expelled to the atmosphere, aiding in maintaining the overall thermal balance of the fuel cell power system 100.

In a step 1122, the control unit 406 continues to dynamically manage the thermal conditions based on ongoing feedback from the plurality of thermocouples 1004. If additional cooling is needed, the control unit 406 can activate supplementary cooling mechanisms or increase the speed of the fan assemblies 108, or the centrifugal fan 202, and the flow rate through the plurality of heat exchangers 200 to bring the temperature of the container 102 and/or fuel cell stack 400 back to the desired range.

For safety, the thermal management system 1000 may be further configured to trigger alerts via the control unit 406 when the temperature crosses safety temperature thresholds for the fuel cell stack 400 and the fuel cell power system 100. An audible alarm, visual alert, or digital communication activates to inform an operator or back-office or remote team, as generally known in the arts.

The container 103 may include a humidity control system in communication with the control unit 406 to maintain optimal humidity levels within the single compartment of the container 102. The humidity control system may utilize a plurality of hybrid sensors that measure humidity and temperature. The plurality of thermocouples may include hybrid sensors which communicates the humidity readings in the container 102 to the control unit 406, providing comprehensive environmental data. These sensors are distributed strategically throughout the container 102 to accurately monitor the internal atmosphere. Once they gather humidity and temperature data, the hybrid sensors relay this information to the control unit 406. The control unit 406, programmed with specific humidity parameters ideal for the operation of the fuel cells, processes this data and activates necessary adjustments. These adjustments might include engaging the plurality of fan assemblies 108, the plurality of heat exchangers 106, or the pump 1006, for modulating the coolant flow and internal the air circulation of the container 102, to maintain the environmental conditions within optimal ranges. By doing so, the humidity control system plays a crucial role in preserving the integrity and efficiency of the fuel cell power system housed within the container 102.

The fuel cell power system 100 may be designed for interoperability, allowing integration with external devices and systems. Standardized connectors and established protocols may be incorporated, facilitating a connection to larger electrical grids to enable the system to supply or draw power based on operational parameters. Further, the control unit 406 within the system 100 may support multiple communication protocols, ensuring compatibility with various grid management systems and external devices.

The fuel cell power system 100 may be configured modularity so that the components, including the fuel cell stack 400, power electronics 40, and the battery 404, are structured for ease of replacement or upgrades. The containerized design provides access to internal components, ensuring component replacement with reduced system downtime.

The thermal management system 1000 allows for an increased power density from the containerized fuel cell power system 100. The increased power density is a direct result of the system's ability to maintain optimal operating temperatures for the fuel cells 400 and associated electronics. By effectively managing the heat generated during operation, the fuel cell power system can operate at higher capacities without the risk of overheating, thereby yielding more power per unit volume of the container. This aspect is particularly crucial in applications where space and weight are at a premium, as it allows for the deployment of more powerful systems in limited spaces.

Additionally, the thermal management system 1000 permits communizing the cooling system elements using high performance fan assemblies removing and eliminating the need for extra or other dedicated component fans for subsystems. The fan assemblies 108 may be high performance centrifugal fans that remove the need for excess subsystem fans. The use of high-performance fan assemblies, such as centrifugal fans 108, means that a single, more efficient cooling mechanism can replace multiple, potentially less efficient subsystem-specific fans. This reduction in the number of fans not only decreases the system's complexity and potential points of failure but also contributes to a lower overall power consumption for cooling. High-performance centrifugal fans are chosen for their ability to move large volumes of air while overcoming system resistance, making them ideal for maintaining the necessary airflow rates for effective cooling across the entire system

From the foregoing, it can be seen that the technology disclosed herein has industrial applicability in a variety of settings that require reliable and efficient thermal management during power generation by hydrogen fuel cell systems, such as renewable energy installations, backup power systems, and industrial power solutions.

What is claimed is:

1. A fuel cell power system comprising:
a container having a single compartment;
a fuel cell stack;
a set of power electronics electrically connected to the fuel cell stack;
a plurality of heat exchangers mounted on a plurality of walls on the container configured for drawing outside air into the container;
a common manifold connecting a plurality of coolant lines to the plurality of heat exchangers, at least one of the plurality of coolant lines circulating hot coolant from the fuel cell power system to the plurality of heat exchangers, and at least one of the plurality of coolant lines circulating cold coolant to the fuel cell stack;
a pump for transferring coolant throughout the plurality of coolant lines; and
a plurality of fan assemblies mounted on top of the container, the plurality of fan assemblies are configured to draw the outside air through the plurality of heat exchangers and expel exhaust air out of the container.

2. The fuel cell power system of claim 1, further comprising:
a duct assembly for each of the plurality of fan assemblies, the duct assembly having an opening for expelling the exhaust air;
a power distribution unit;
a battery;
a DC choke set, the DC choke set being positioned proximate the top of the container and proximate to one of the plurality of fan assemblies; and
fuel cell air filters for cleaning intake air for the fuel cell stack.

3. The fuel cell power system of claim 1, further comprising:
a thermostat;
a plurality of thermocouples provided throughout the container and in communication with the thermostat; and
a control unit in communication with the thermostat, the fuel cell stack, the battery, the plurality of heat exchangers, the pump, the plurality of fan assemblies, and the set of power electronics, the control unit being configured to activate the pump, the plurality of heat exchangers, and the plurality of fan assemblies.

4. The fuel cell power system of claim 1, further comprising a coolant reservoir in fluid communication with the plurality of coolant lines, storing a reserve of the coolant for circulation.

5. The fuel cell power system of claim 1, further comprising a humidity control system in the container to maintain optimal humidity levels container.

6. The fuel cell power system of claim 2, wherein the plurality of fan assemblies include at least two centrifugal fans each having the duct assembly oriented to channel the exhaust air out of the container in opposing directions.

7. The fuel cell power system of claim 2, wherein:
the container includes insulation layers on an interior of the plurality of walls;
the pump is a variable-speed pump, adjusting a coolant flow in the plurality of coolant lines based on thermal load requirements;
the plurality of heat exchangers are coated with anti-corrosive materials to ensure longevity in various environmental conditions, the plurality of heat exchangers including each having an inlet louver to prevent ingress of water and debris;
the plurality of fan assemblies are designed to adjust airflow dynamically based on the thermal needs of the fuel cell power system; and
the opening of the duct assembly includes an exhaust louver to prevent ingress of water and debris.

8. The fuel cell power system of claim 7, further comprising an interface configured to connect to external devices and to supply power from fuel cell power system.

9. A thermal management system for a containerized fuel cell power system comprising:
a plurality of heat exchangers integrated in a plurality of walls of a container, each heat exchanger configured to draw an outside air into the container, the container having a fuel cell and power electronics;
a common manifold connecting a plurality of coolant lines to the plurality of heat exchangers;
a pump configured to transfer coolant throughout the plurality of coolant lines, at least one of the plurality of coolant lines configured to circulate the coolant from the fuel cell to the plurality of heat exchangers, and at least one of the plurality of coolant lines configured to circulate the coolant to the fuel cell;
a plurality of fan assemblies mounted on the container, the plurality of fan assemblies configured to draw the outside air through the plurality of heat exchangers into the container and further configured to expel exhaust air from the container;
a thermostat and a plurality of thermocouples in communication with the thermostat, the plurality of thermocouples are provided throughout the containerized fuel cell power system; and
a control unit in communication with the thermostat, the pump, and the plurality of fan assemblies, the control unit configured to modulate the pump and operations of the plurality of fan assemblies based on temperature readings received from the thermostat.

10. The thermal management system of claim 9, wherein:
the control unit is in further communication with the fuel cell, the battery, the plurality of heat exchangers, the pump, the plurality of fan assemblies, and the power electronics; and
the control unit is configured to activate and deactivate the pump, the power electronics, the fuel cell, the plurality of heat exchangers, and the plurality of fan assemblies.

11. The thermal management system of claim 9, wherein the plurality of fan assemblies are mounted on top of the container.

12. The thermal management system of claim 9, further comprising:
a duct assembly for each of the plurality of fan assemblies, the duct assembly having an opening for expelling the exhaust air;
the power electronics includes a power distribution unit, a battery, and a DC choke set, the DC choke set being positioned proximate the top of the container and proximate to one of the plurality of fan assemblies; and
an air filter for filtering intake air into the fuel cell.

13. The thermal management system of claim 9, further comprising a humidity control system in the container to maintain optimal humidity levels within the container.

14. The thermal management system of claim 12, wherein the plurality of fan assemblies include at least two centrifugal fans each having the duct assembly oriented to channel the exhaust air out of the container in opposing directions.

15. The thermal management system of claim 12, wherein:
the container includes insulation layers on an interior of the plurality of walls;
the pump is a variable-speed pump, adjusting coolant flow based on thermal load requirements;
the plurality of heat exchangers are coated with anti-corrosive materials to ensure longevity in various environmental conditions;
the plurality of heat exchangers include a first louver to prevent ingress of water and debris when air is draw into the container;
the plurality of fan assemblies are designed to adjust airflow dynamically based on the thermal needs of the containerized fuel cell power system; and
the opening of the duct assembly includes a second louver to prevent ingress of water and debris.

16. The thermal management system of claim 15, further comprising an interface configured to connect to external devices and to supply power from the fuel cell power system.

17. A method for producing electric power in a containerized fuel cell power system, the method comprising:
providing a fuel cell stack, power electronics, and a control unit within a container;
integrating a plurality of heat exchangers into walls of the container;
mounting a plurality of fan assemblies on the container for thermal management;
activating the containerized fuel cell power system for electric power generation; and
initiating power generation in the fuel cell stack by transforming hydrogen and oxygen into electricity and water.

18. The method of claim 17, the method further comprising:
providing a plurality of thermocouples in communication with the control unit in the container, the plurality of thermocouples each communicate a temperature signal to the control unit;
continuously monitoring a temperature of the coolant and the container via the control unit and the plurality of thermocouples;
circulating a coolant through a plurality of coolant lines provided throughout the containerized fuel cell power system;
drawing in outside air through the plurality of heat exchangers to cool the plurality of coolant lines; and
expelling exhaust air out of the container, via the plurality of fan assemblies mounted on a roof of the container.

19. The method of claim 18, the method further comprising:
modulating, via the control unit, a circulation of the coolant, the plurality of heat exchangers and the plurality of fan assemblies when the temperature deviates from a predetermined temperature range.

20. The method of claim 18, the method further comprising:
providing an interface for external devices;
connecting an external device to the fuel cell power system via the interface; and
supplying power from the containerized fuel cell power system to the external device.
